(19) United States
(12) Patent Application Publication
(10) Pub. No.: US 2022/0361322 A1
(43) Pub. Date: Nov. 10, 2022

(54) DISPLAY PANEL AND DISPLAY MODULE

(71) Applicant: Wuhan China Star Optoelectronics Semiconductor Display Technology Co., Ltd., Wuhan (CN)

(72) Inventor: Bi CHEN, Wuhan (CN)

(21) Appl. No.: 16/630,472

(22) PCT Filed: Oct. 17, 2019
(86) PCT No.: PCT/CN2019/111629

§ 371 Date: Jan. 13, 2020

(30) Foreign Application Priority Data
Jun. 12, 2019 (CN) 201910505268.3

(51) Int. Cl. H05K 1/02; H05K 1/11

(52) U.S. Cl. CPC H05K 1/0296; H05K 1/115; H05K 2201/10128

(57) ABSTRACT

A display panel and a display module are disclosed. The display panel includes a second lead wire disposed corresponding to a first lead wire in an intersecting arrangement and insulated from the first lead wire. A first projection area is defined by a projection of the first lead wire projected on the second lead wire, and a second projection area is defined by a projection of the second lead wire projected on the first lead wire. A via hole is disposed in the first projection area or the second projection area. The display panel is configured to mitigate capacitance interference between the first lead wire and the second lead wire, and to further improve display performance of the display panel.

### BACKGROUND OF INVENTION

### 1. Field of Invention

The present invention relates to a technical field of displays, and particularly to, a display panel and a display module.

### 2. Related Art

With development of touch technology, touch panels are widely used in smart electronic devices, such as mobile phones, televisions, wearable devices, and public inquiry devices.

Oncell technology is a means implemented by directly forming a touch sensing pattern on a display panel, and can be divided into a mutual capacitance mode and a self-capacity mode based on a principle of touch control. The mutual compatibility mode, at present, is the mainstream. The mutual capacitance mode is realized by a structure configured with drive electrodes and sensing electrodes. In designing special-shaped touch for bilateral driving, a situation of crossover of driving leads and the sensing leads is inevitable in a special-shaped area.

When driving leads and sensing electrode leads are designed to cross each other at different layers, a sensing electrode capacitance is caused to be abnormal in an intersection area of the driving leads and sensing electrode leads, adversely affecting display performance of display panels.

### SUMMARY OF INVENTION

An object of the present invention is to provide a display panel and a display module to overcome the problem that when a driving lead and a sensing electrode lead are designed to cross each other at different layers, a sensing electrode capacitance is caused to be abnormal in an intersection area of the driving lead and the sensing electrode lead, adversely affecting display performance of a display panel in prior art.

In a first aspect, the present application provides a display panel, comprising a first metal layer and a second metal layer, wherein the second metal layer comprises a first electrode and a second electrode, the first electrode is connected to the first metal layer through a first lead wire, and the second electrode is connected to the first metal layer through a second lead wire; wherein the first lead wire is disposed in a first direction, the second lead wire is disposed corresponding to the first lead wire in an intersecting arrangement in a second direction and is insulated from the first lead wire, a first projection area is defined by a projection of the first lead wire projected on the second lead wire, and a second projection area is defined by a projection of the second lead wire projected on the first lead wire; wherein a via hole is disposed in the first projection area or/and the second projection area; and wherein the first projection area has a width less than that of a second target area defined as an area of the second lead wire other than the first projection area; and the second projection area has a width less than that of a first target area defined as area on the first lead wire other than the second projection area.

In a second aspect, the present application provides a display panel, comprising a first metal layer and a second metal layer, wherein the second metal layer comprises a first electrode and a second electrode, the first electrode is connected to the first metal layer through a first lead wire, and the second electrode is connected to the first metal layer through a second lead wire; wherein the first lead wire is disposed in a first direction, the second lead wire is disposed corresponding to the first lead wire in an intersecting arrangement in a second direction and is insulated from the first lead wire, a first projection area is defined by a projection of the first lead wire projected on the second lead wire, and a second projection area is defined by a projection of the second lead wire projected on the first lead wire; and wherein a via hole is disposed in the first projection area or/and the second projection area.

Further, a first via hole is disposed in the first projection area.

Further, the second projection area has a width less than that of a first target area, wherein the first target area is defined as an area of the first lead wire other than the second projection area.

Further, a second via hole is disposed in the second projection area.

Further, the first projection area has a width less than that of a second target area, wherein the second target area is defined as an area of the second lead wire other than the first projection area.

Further, the via hole is circular, rectangular, or elliptical in shape.

Further, a number of the via hole is more than one.

Further, the first projection area has a width less than that of a second target area, wherein the second target area is defined as an area of the second lead wire other than the first projection area.

Further, the second projection area has a width less than that of a first target area, wherein the first target area is defined as an area of the first lead wire other than the second projection area.

In a third aspect, the present application provides a display module comprising any one of the above-mentioned display panels.

Further, the display panel comprises a first metal layer and a second metal layer, wherein the second metal layer comprises a first electrode and a second electrode, the first electrode is connected to the first metal layer through a first lead wire, and the second electrode is connected to the first metal layer through a second lead wire; wherein the first lead wire is disposed in a first direction, the second lead wire is disposed corresponding to the first lead wire in an intersecting arrangement in a second direction and is insulated from the first lead wire, a first projection area is defined by a projection of the first lead wire projected on the second lead wire, and a second projection area is defined by a projection of the second lead wire projected on the first lead wire; and wherein a via hole is disposed in the first projection area or/and the second projection area.

Further, a first via hole is disposed in the first projection area.

Further, the second projection area has a width less than that of a first target area, wherein the first target area is defined as an area of the first lead wire other than the second projection area.

Further, a second via hole is disposed in the second projection area.

Further, the first projection area has a width less than that of a second target area, wherein the second target area is defined as an area of the second lead wire other than the first projection area.

Further, the via hole is circular, rectangular, or elliptical in shape.

Further, a number of the via hole is more than one.

Further, the first projection area has a width less than that of a second target area, wherein the second target area is defined as an area of the second lead wire other than the first projection area.

Further, the second projection area has a width less than that of a first target area, wherein the first target area is defined as an area of the first lead wire other than the second projection area.

The present application has advantageous effects as follows: based on the display module of the present invention, by setting the via hole in the first projection area corresponding to the first lead wire or in the second projection area corresponding to the second lead wire of the display panel, an area of a projection area between the first lead wire and the second lead wire is reduced, so that capacitance interference between the first lead wire and the second lead wire is mitigated, thereby improving display performance of the display panel.

### BRIEF DESCRIPTION OF DRAWINGS

To better illustrate embodiments or technical solutions in the prior art, a brief description of the drawings used in the embodiments or the prior art description will be given below. Obviously, the accompanying drawings in the following description merely show some embodiments of the present invention, and a person skilled in the art may still derive other drawings from these accompanying drawings without creative efforts.

FIG. 1 is a schematic enlarged structural view of an embodiment of the present invention.

FIG. 2 is another schematic enlarged structural view of an embodiment of the present invention.

FIG. 3 is another schematic enlarged structural view of an embodiment of the present invention.

FIG. 4 is another schematic enlarged structural view of an embodiment of the present invention.

FIG. 5 is another schematic enlarged structural view of an embodiment of the present invention.

### DESCRIPTION OF PREFERRED EMBODIMENTS

The following embodiments are referring to the accompanying drawings for exemplifying specific implementable embodiments of the present invention. Directional terms described by the present invention, such as upper, lower, front, back, left, right, inner, outer, side, etc., are only directions by referring to the accompanying drawings, and thus the used directional terms are used to describe and understand the present invention, but the present invention is not limited thereto.

The drawings and description are to be regarded as illustrative in nature and not restrictive. Like reference numerals designate like elements throughout the specification. In addition, the size and thickness of each component shown in the drawings are arbitrarily shown for understanding and ease of description, but the present invention is not limited thereto.

In the drawings, the thickness of layers, films, panels, regions, etc., are exaggerated for clarity. In the drawings, for understanding and ease of description, the thicknesses of some layers and areas are exaggerated. It will be understood that, when an element such as a layer, film, region, or substrate is referred to as being “on” another element, it can be directly on the other element or intervening elements may also be present.

In addition, in the specification, unless explicitly described to the contrary, the word “comprise” and variations such as “comprises” or “comprising” will be understood to imply the inclusion of stated elements but not the exclusion of any other elements. Furthermore, in the specification, “on” implies being positioned above or below a target element and does not imply being necessarily positioned on the top on the basis of a gravity direction.

To further expound the technical solution adopted in the present invention and the advantages thereof, a detailed description is given to a preferred embodiment of the present invention and the attached drawings.

With respect to display panels in current technology, when driving leads and sensing electrode leads are designed to cross each other at different layers, a sensing electrode capacitance is caused to be abnormal in an intersection area of the driving leads and sensing electrode leads, adversely affecting display performance of display panels.

The present invention provides a display panel. The display panel includes a first metal layer and a second metal layer. The second metal layer includes a first electrode and a second electrode. The first electrode is connected to the first metal layer through a first lead wire, and the second electrode is connected to the first metal layer through a second lead wire.

The first lead wire is disposed in a first direction, the second lead wire is disposed corresponding to the first lead wire in an intersecting arrangement in a second direction and is insulated from the first lead wire, a first projection area is defined by a projection of the first lead wire projected on the second lead wire, and a second projection area is defined by a projection of the second lead wire projected on the first lead wire.

A via hole is disposed in the first projection area or/and the second projection area.

Based on the display panel of the present invention, by setting the via hole in the first projection area corresponding to the first lead wire or in the second projection area corresponding to the second lead wire of the display panel, an area of a projection area between the first lead wire and the second lead wire is reduced, so that capacitance interference between the first lead wire and the second lead wire is mitigated, thereby improving display performance of the display panel.

In certain embodiments of the present invention, the first lead wire may be composed of a plurality of sub-leads, and the first lead wire composed of the sub-leads has a shape of certain length and width. The first lead wire is disposed in the display panel. Likewise, the second lead wire may be composed of a plurality of sub-leads, and the second lead wire composed of the sub-leads has a shape of certain length and width. The second lead wire is disposed in the display panel.

Particularly, the first lead wire is disposed in a first direction in a display module, the second lead wire is disposed in a second direction in the display module, wherein the first lead wire and the second lead wire are disposed corresponding to each other in an intersecting arrangement in the display module, and the first lead wire and the second lead wire are insulated from each other. Furthermore, a first projection area is defined by a projection of the first lead wire projected on the second lead wire, and a second projection area is defined by a projection of the second lead wire projected on the first lead wire.

As shown in FIG. 1, it is a schematic view of an embodiment of the present invention. The first lead wire 10 is disposed in a first direction, the second lead wire 20 is disposed corresponding to the first lead wire 10 in an intersecting arrangement in a second direction and is insulated from the first lead wire. A first projection area is defined by a projection of the first lead wire 10 projected on the second lead wire 20, and a second projection area is defined by a projection of the second lead wire 20 projected on the first lead wire 10. In certain embodiments of the present invention, as shown in FIG. 1, a first via hole 101 may be disposed in the first projection area, and shape and number of the first via hole are not limited therein.

Specifically, the first via hole 101 of the first projection area may be circular, rectangular, or ellipse in shape, and a number of the first via hole 101 may be two, three, or four.

An area of the first projection area is reduced because the first via hole 101 is disposed in the first projection area, thereby further reducing a contact area of the first lead wire 10 and the second lead wire 20, as well as reducing capacitance interference between the first lead wire 10 and the second lead wire 20, and improving display performance of the display panel.

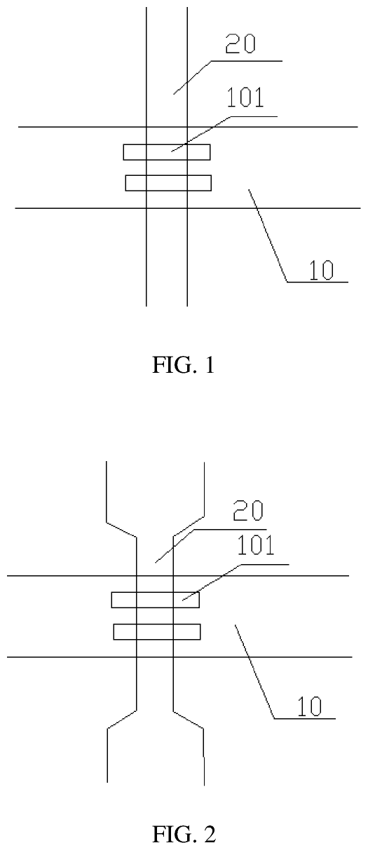

As shown in FIG. 2, it is another schematic enlarged structural view of another embodiment of the present invention. Based on the above-mentioned embodiment, a width of the second projection area can further be reduced, so that the second projection area has a width less than that of a first target area. In such an embodiment, a width of the first target area is defined as a width of an area on the first lead wire 10 other than the second projection area. In this manner, width of the second projection area is less than that of the first lead wire 10, thereby reducing a contact area of the first lead wire 10 and the second lead wire 20, as well as mitigating capacitance interference between the first lead wire 10 and the second lead wire 20, and improving display performance of the display panel.

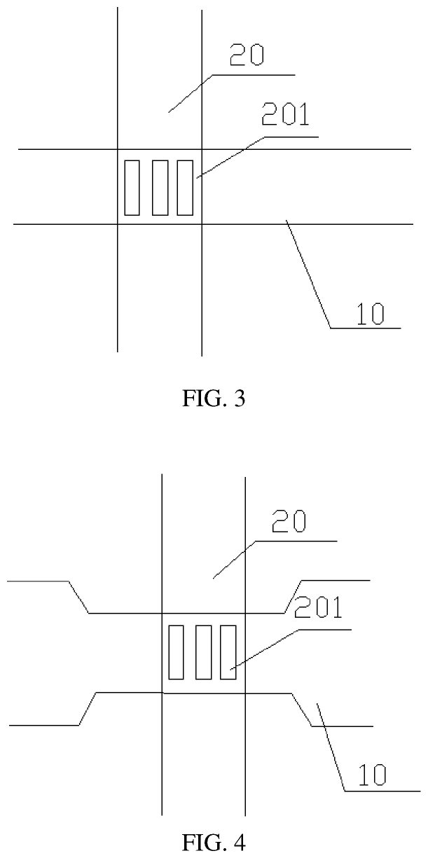

As shown in FIG. 3, it is a schematic view of another embodiment of the present invention. In this embodiment, a second via hole 201 may be disposed in the second projection area, and shape and number of the second via hole are not limited therein. For example, the second via hole 201 may be circular, rectangular, or ellipse in shape, and a number of the first via hole 101 may be two, three, or four. An area of the second projection area is reduced because the second via hole 201 is disposed in the second projection area, thereby further reducing a contact area of the first lead wire 10 and the second lead wire 20, as well as reducing capacitance interference between the first lead wire 10 and the second lead wire 20, and improving display performance of the display panel.

As shown in FIG. 4, it is another schematic enlarged structural view of another embodiment of the present invention. Based on the above-mentioned embodiment, a width of the first projection area can be further reduced, so that the first projection area has a width less than that of a second target area. In such an embodiment, a width of the second target area is defined as a width of an area of the second lead wire 20 other than the first projection area. In this manner, width of the first projection area is less than that of the second lead wire 20, thereby reducing a contact area of the first lead wire 10 and the second lead wire 20, as well as mitigating capacitance interference between the first lead wire 10 and the second lead wire 20, and improving display performance of the display panel.

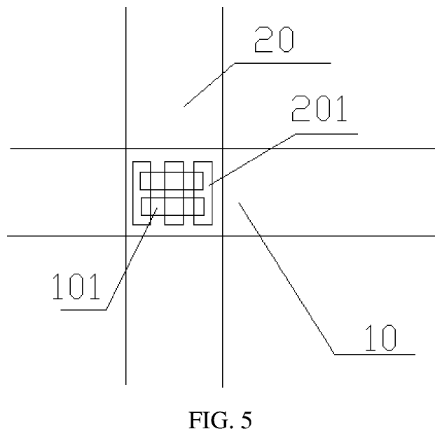

As shown in FIG. 5, it is a schematic view of another embodiment of the present invention. In this embodiment, via holes may be disposed in both the first projection area and the second projection area, that is, a first via hole 101 is disposed in the first projection area, and a second via hole 201 is disposed in the second projection area, thereby further reducing a contact area of the first lead wire 10 and the second lead wire 20, as well as mitigating capacitance interference between the first lead wire 10 and the second lead wire 20, and improving display performance of the display panel.

It should be noted that shape and number of both the first via hole 101 disposed in the first projection area and the second via hole 201 disposed in the second projection area are not limited herein, as well as methods for fabricating via holes, for which specific operations can refer to the prior art.

In certain embodiments of the present invention, a width of the first projection area can further be reduced, so that the first projection area has a width less than that of a second target area. In such an embodiment, a width of the second target area is defined as a width of an area of the second lead wire 20 other than the first projection area. In this manner, width of the first projection area is less than that of the second lead wire 20, thereby reducing a contact area of the first lead wire 10 and the second lead wire 20, as well as mitigating capacitance interference between the first lead wire 10 and the second lead wire 20, and improving display performance of the display panel.

In other embodiments of the present invention, a width of the first projection area can be reduced, so that the first projection area has a width less than that of a second target area. In such an embodiment, a width of the second target area is defined as a width of an area of the second lead wire other than the first projection area.

Also, on the basis that the width of the first projection area is reduced, a width of the second projection area is reduced, so that the second projection area has a width less than that of the first target area. In such an embodiment, a width of the first target area is defined as a width of an area on the first lead wire other than the second projection area.

By reducing the width of both the first projection area and the second projection area, a contact area of the first lead wire 10 and the second lead wire 20 is further reduced, thereby mitigating capacitance interference between the first lead wire 10 and the second lead wire 20, as well as improving display performance of the display panel.

It should be noted that in the above-mentioned embodiment, the first electrode and the second electrode are a driving electrode and a sensing electrode, respectively, and the first lead wire and the second lead wire are a driving lead and an inductive lead, respectively. The first electrode is corresponding to the first lead wire, and the second electrode is corresponding to the second lead wire. For example, the first electrode is a driving electrode, the second electrode is a sensing electrode, the first lead wire is a driving lead, and the second lead wire is an inductive lead.

The present invention further provides a display module. The display module includes the above-mentioned display panel. Based on the display module of the present invention, by setting the via hole in the first projection area corresponding to the first lead wire or in the second projection area corresponding to the second lead wire of the display panel, an area of a projection area between the first lead wire and the second lead wire is reduced, so that capacitance interference between the first lead wire and the second lead wire is mitigated, thereby improving display performance of the display panel.

According to the above object of the present invention, a display module including the aforementioned display panel is provided. The working principle of the display module provided in this embodiment is consistent with the working principle of the embodiment of the aforementioned display panel. For the specific structural connection and working principle, please refer to the display panel of the aforementioned embodiments, and details are not described herein again.

According to the above object of the present invention, an electronic device including the aforementioned display panel is provided. The working principle of the electronic device provided in this embodiment is consistent with the working principle of the embodiment of the aforementioned display panel. For the specific structural connection and working principle, please refer to the display panel of the aforementioned embodiments, and details are not described herein again.

Accordingly, although the present invention has been disclosed as a preferred embodiment, it is not intended to limit the present invention. Those skilled in the art without departing from the spirit and scope of the present invention may make various changes or modifications, and thus the scope of the present invention should be after the appended claims and their equivalents.

What is claimed is:

1. A display panel, comprising:
a first metal layer and a second metal layer, wherein the second metal layer comprises a first electrode and a second electrode, the first electrode is connected to the first metal layer through a first lead wire, and the second electrode is connected to the first metal layer through a second lead wire;
wherein the first lead wire is disposed in a first direction, the second lead wire is disposed corresponding to the first lead wire in an intersecting arrangement in a second direction and is insulated from the first lead wire, a first projection area is defined by a projection of the first lead wire projected on the second lead wire, and a second projection area is defined by a projection of the second lead wire projected on the first lead wire;
wherein a via hole is disposed in the first projection area or/and the second projection area;
wherein the first projection area has a width less than that of a second target area defined as an area of the second lead wire other than the first projection area; and
the second projection area has a width less than that of a first target area defined as area on the first lead wire other than the second projection area.

2. A display panel, comprising:
a first metal layer and a second metal layer, wherein the second metal layer comprises a first electrode and a second electrode, the first electrode is connected to the first metal layer through a first lead wire, and the second electrode is connected to the first metal layer through a second lead wire;
wherein the first lead wire is disposed in a first direction, the second lead wire is disposed corresponding to the first lead wire in an intersecting arrangement in a second direction and is insulated from the first lead wire, a first projection area is defined by a projection of the first lead wire projected on the second lead wire, and a second projection area is defined by a projection of the second lead wire projected on the first lead wire; and
wherein a via hole is disposed in the first projection area or/and the second projection area.

3. The display panel of claim 2, wherein a first via hole is disposed in the first projection area.

4. The display panel of claim 3, wherein the second projection area has a width less than that of a first target area, wherein the first target area is defined as an area of the first lead wire other than the second projection area.

5. The display panel of claim 2, wherein a second via hole is disposed in the second projection area.

6. The display panel of claim 5, wherein the first projection area has a width less than that of a second target area, wherein the second target area is defined as an area of the second lead wire other than the first projection area.

7. The display panel of claim 2, wherein the via hole is circular, rectangular, or elliptical in shape.

8. The display panel of claim 2, wherein a number of the via hole is more than one.

9. The display panel of claim 2, wherein the first projection area has a width less than that of a second target area, wherein the second target area is defined as an area of the second lead wire other than the first projection area.

10. The display panel of claim 2, wherein the second projection area has a width less than that of a first target area, wherein the first target area is defined as an area of the first lead wire other than the second projection area.

11. A display module, comprising the display panel of claim 1.

12. The display module of claim 11, wherein the display panel comprises a first metal layer and a second metal layer, wherein the second metal layer comprises a first electrode and a second electrode, the first electrode is connected to the first metal layer through a first lead wire, and the second electrode is connected to the first metal layer through a second lead wire;
wherein the first lead wire is disposed in a first direction, the second lead wire is disposed corresponding to the first lead wire in an intersecting arrangement in a second direction and is insulated from the first lead wire, a first projection area is defined by a projection of the first lead wire projected on the second lead wire, and a second projection area is defined by a projection of the second lead wire projected on the first lead wire; and
wherein a via hole is disposed in the first projection area or/and the second projection area.

13. The display module of claim 12, wherein a first via hole is disposed in the first projection area.

14. The display module of claim 13, wherein the second projection area has a width less than that of a first target area, wherein the first target area is defined as an area of the first lead wire other than the second projection area.

15. The display module of claim 12, wherein a second via hole is disposed in the second projection area.

16. The display module of claim 15, wherein the first projection area has a width less than that of a second target area, wherein the second target area is defined as an area of the second lead wire other than the first projection area.

17. The display module of claim 12, wherein the via hole is circular, rectangular, or elliptical in shape.

18. The display module of claim 12, wherein a number of the via hole is more than one.

19. The display module of claim 12, wherein the first projection area has a width less than that of a second target area, wherein the second target area is defined as an area of the second lead wire other than the first projection area.

20. The display module of claim 12, wherein the second projection area has a width less than that of a first target area, wherein the first target area is defined as an area of the first lead wire other than the second projection area.
